(19) United States
(12) Patent Application Publication
(10) Pub. No.: US 2014/0131079 A1
(43) Pub. Date: May 15, 2014

(54) Conductive Nano Ink Composition and Electrode Line and Transparent Electrode Using the Same

(71) Applicant: Enjet Co., Ltd., Gyeonggi-do (KR)

(72) Inventor: Do-Young Byun, Seoul (KR)

(73) Assignee: Enjet Co., Ltd., Gyeonggi-do (KR)

(21) Appl. No.: 14/075,834

(22) Filed: Nov. 8, 2013

(30) Foreign Application Priority Data
Nov. 9, 2012 (KR) 10-2012-0126998

(51) Int. Cl. H05K 1/02; C09D 11/00

(52) U.S. Cl. CPC H05K 1/0274; C09D 11/52
USPC 174/257; 252/500; 252/511; 252/512; 252/513; 252/514

(57) ABSTRACT

Disclosed is a conductive nano ink composition which contains 0.05 to 15 parts by weight of a high molecular compound having a molecular weight of 100,000 to 1,000,000 and comprising at least one between a natural high-molecular compound and a synthetic high-molecular compound; 1 to 6 parts by weight of a wetting dispersant; and 10 to 100 parts by weight of an organic solvent, per 100 parts by weight of a conductive nano structure, thereby providing an electrode line having a narrow line width due to its uniform viscosity and excellent electrical properties. Further, it is possible to provide a transparent electrode excellent in light transmittance and electric conductivity as it is patterned using the conductive nano ink composition.

### CROSS-REFERENCE TO RELATED APPLICATIONS

The application is a national stage application of KR 10-2012-0126998 filed on Nov. 9, 2012, the disclosure of which is incorporated by reference herein.

### BACKGROUND OF THE INVENTION

(a) Field of the Invention

The present invention relates to a conductive nano ink composition, and an electrode line and transparent electrode using the same, and more particularly to a conductive nano ink composition for electrohydrodynamic jet-printing, in which a conductive nano structure, at least one of a natural high-molecular compound and a synthetic high-molecular compound, a wetting dispersant and an organic solvent are mixed in optimal contents to have certain viscosity and electric conductivity, so that an electrode line of a transparent electrode can be patterned to have a line width of 10 μm or less through the electrohydrodynamic jet-printing, thereby providing the transparent electrode excellent in electric conductivity and optical properties.

(b) Description of the Related Art

Transparent electrode plastic or transparent electrode glass has been used in processes for a touch panel, an organic light emitting diode (OLED) flexible display, an organic solar cell, etc. which are growing rapidly, as well as a liquid crystal display (LCD), a plasma display panel (PDP) or the like existing display. In general, an indium tin oxide (ITO) electrode fabricated by a sputtering method has been employed for such a transparent electrode. This is because the ITO is easy to form a thin film, is excellent in light transmittance properties, and has relatively low electric resistance. However, a main material, i.e., indium has problems that material costs increase due to rise in the price, its market is instable, exhaustion is expected, a device is deteriorated due to diffusion of indium, a reducing characteristic is strong under hydrogen-plasma treatment, a crack or the like bending instability arises on a flexible substrate, and so on. In particular, the ITO transparent thin film is fabricated by a sputtering method under a high temperature and vacuum condition, and thus many problems arise in successive processes for a large area thin film. Accordingly, there is a need of developing a transparent electrode showing optimal physical properties on a plastic substrate to be applied to a flexible electronic device. Conventional ITO has a problem that the substrate is deformed due to difference in a coefficient of thermal expansion between the ITO electrode and the plastic substrate while being processed or driven, and surface resistance is varied due to broken electrodes as the electrode substrate is bent.

As an alternative to ITO, an organic transparent electrode using a conducting polymer or a carbon nano tube (CNT), and a graphene or the like organic material has been developed. However, the organic transparent electrode is lowered in transparency since it needs to form a thick film for sufficient electric resistance.

Meanwhile, to solve the problems of the conventional transparent electrode, there has been proposed a method in which conductive liquid is printed in the form of a grid and used as the transparent electrode. In particular, a metal grid is printed on a plastic or glass substrate, thereby fabricating the transparent electrode having very low resistance and high transparency. To this end, gravure offset printing, inkjet printing or the like method has been used.

However, the foregoing printing method has problems that it is difficult to make the line width of the grid be equal to or less than 10 μm, and the height of the grid electrode line has high resistance because its height is low (about 200 nm). Although the transparent electrode needs to have good optical characteristics, these grid electrodes cause optical problems of a haze, a visible problem that the grids are visible by backlight when the grid electrodes are applied to a display, a touch panel, etc. Further, the foregoing printing method has a problem that metal is directly exposed to air and oxidized. Meanwhile, feasibility of patterning liquid having a low viscosity of 100 cP or less through the electrohydrodynamic jet-printing has been considered to solve such a problem, but there has been no report about development of a nano ink composition having high viscosity and suitable for this method.

### SUMMARY OF THE INVENTION

Accordingly, the present invention is conceived to solve the forgoing problems, and an aspect of the present invention is to provide a conductive nano ink composition optimized as spraying liquid for electrohydrodynamic jet-printing, in which a conductive nano structure, a high-molecular compound, a wetting dispersant, and an organic solvent are mixed in optimal contents to improve both light transmittance and electric characteristic.

Also, an aspect of the present invention is to provide a conductive nano ink composition, which contains a high-molecular compound, i.e., at least one of a natural high-molecular compound or a synthetic high-molecular compound, excellent in controlling viscosity and thus has a viscosity of 1,000 to 100,000cP, so that an electrode line of 10 μm or less can be patterned. Here, the high-molecular compound is combined and coated to a conductive nano structure, thereby providing the conductive nano ink composition more excellent in optical properties and preventing the conductive nano structure from being oxidized.

Further, an aspect of the present invention is to provide an electrode line and a transparent electrode, in which the conductive nano ink composition is patterned as an electrode line through electrohydrodynamic jet-printing so that the conductive nano structure can be aligned by itself.

Also, an aspect of the present invention is to provide an electrode line and a transparent electrode in which a substrate is coated with a conductive material and improved in electric conductivity, and the electrode line is patterned through electrohydrodynamic jet-printing, and to provide a transparent electrode in which a coating layer is formed on the electrode patterned with the conductive nano ink composition through the electrohydrodynamic jet-printing on the substrate, thereby reducing roughness and thus making physical and optical properties better. Further, an aspect of the present invention is to provide a transparent electrode in which a coating layer made of a conductive material is formed on both a substrate and an electrode pattern, thereby being excellent in physical properties as well as electrical and optical properties.

In accordance with an aspect of the present invention, there is provided a conductive nano ink composition including: 0.05 to 15 parts by weight of a high molecular compound having a molecular weight of 100,000 to 1,000,000 and including at least one between a natural high-molecular compound and a synthetic high-molecular compound; 1 to 6 parts by weight of a wetting dispersant; and 10 to 100 parts by weight of an organic solvent per 100 parts by weight of a conductive nano structure.

The conductive nano structure may include at least one of a nano particle, a nano wire, a nano rod, a nano pipe, a nano belt and a nano tube; and the conductive nano structure may include a nano structure or a carbon nano tube or combination thereof, the conductive nano structure contains one or more selected from a group consisting of gold (Au), silver (Ag), aluminum (Al), nickel (Ni), zinc (Zn), copper (Cu), silicon (Si) and titanium (Ti).

The natural high-molecular compound may include at least one among chitosan, gelatin, collagen, elastin, hyaluronic acid, cellulose, silk fibroin, phospholipids and fibrinogen. Further, the synthetic high-molecular compound may include at least one among poly(lactic-co-glycolic acid) (PLGA), poly(lactic acid) (PLA), poly(3-hydroxybutyrate-hydroxyvalerate (PHBV), polydioxanone (PDO), polyglycolic acid (PGA), poly(lactide-caprolactone) (PLCL), poly(e-caprolactone) (PCL), poly-L-lactic acid (PLLA), poly(ether urethane urea) (PEUU), cellulose acetate, polyethylene oxide (PEO), poly(ethylene vinyl alcohol (EVOH), polyvinyl alcohol (PVA), polyethylene glycol (PEG) and polyvinylpyrrolidone (PVP).

The organic solvent may include at least one among an alcohol solvent, an ester solvent, and an ether solvent.

Here, the conductive nano ink composition may have a viscosity of 1,000 to 100,000 cP and an electric conductivity of 10⁻¹⁰ to 10⁻¹ S/m.

In accordance with another aspect of the present invention, there is provided an electrode line of a conductive nano ink composition, the conductive nano ink composition including: 0.05 to 15 parts by weight of a high molecular compound having a molecular weight of 100,000 to 1,000,000 and including at least one between a natural high-molecular compound and a synthetic high-molecular compound; 1 to 6 parts by weight of a wetting dispersant; and 10 to 100 parts by weight of an organic solvent, per 100 parts by weight of a conductive nano structure.

The conductive nano structure may include at least one of a nano particle, a nano wire, a nano rod, a nano pipe, a nano belt and a nano tube; and the conductive nano structure may include a nano structure or a carbon nano tube or combination thereof, the conductive nano structure contains one or more selected from a group consisting of gold (Au), silver (Ag), aluminum (Al), nickel (Ni), zinc (Zn), copper (Cu), silicon (Si) and titanium (Ti).

The natural high-molecular compound may include at least one among chitosan, gelatin, collagen, elastin, hyaluronic acid, cellulose, silk fibroin, phospholipids and fibrinogen. Further, the synthetic high-molecular compound may include at least one among poly(lactic-co-glycolic acid) (PLGA), poly(lactic acid) (PLA), poly(3-hydroxybutyrate-hydroxyvalerate (PHBV), polydioxanone (PDO), polyglycolic acid (PGA), poly(lactide-caprolactone) (PLCL), poly(e-caprolactone) (PCL), poly-L-lactic acid (PLLA), poly(ether urethane urea) (PEUU), cellulose acetate, polyethylene oxide (PEO), poly(ethylene vinyl alcohol (EVOH), polyvinyl alcohol (PVA), polyethylene glycol (PEG) and polyvinylpyrrolidone (PVP).

Here, the electrode line may have a line width of 0.01 to 10 μm.

In accordance with still another aspect of the present invention, there is provided a transparent electrode including: a substrate; and an electrode pattern where the foregoing electrode line is patterned on the substrate. The conductive nano structure of the electrode line patterned on the substrate may be self-aligned in the same orientation as a printing direction, and the substrate may be coated with a carbon nano tube, a graphene or poly(3,4-ethylenedioxythiophene)(PEDOT).

In addition, the electrode pattern may include a plurality of electrode lines, and the plurality of electrode lines may be patterned to have a parallel structure or a mesh structure.

The transparent electrode may further include a coating layer on the substrate where the electrode line is patterned, wherein the coating layer includes a carbon nano tube, a graphene or poly(3,4-ethylenedioxythiophene)(PEDOT). Here, wherein the coating layer may have a thickness of 10 to 300nm.

### BRIEF DESCRIPTION OF THE DRAWINGS

The above and/or other aspects of the present invention will become apparent and more readily appreciated from the following description of the exemplary embodiments, taken in conjunction with the accompanying drawings, in which:

FIG. 1 shows a photograph (a) where a conductive nano ink composition is discharged from a discharging unit of an electrohydrodynamic jet-printing device according to an exemplary embodiment of the present invention, and a photograph (b) where a conductive nano ink composition is discharged from a discharging unit of an electrohydrodynamic jet-printing device departing from the scope of the present invention;

FIG. 2 shows a scanning electron microscope (SEM) photograph (a) of an electrode pattern using the conductive nano ink composition according to an exemplary embodiment of the present invention, and a SEM photograph (b) of an electrode pattern using the conductive nano ink composition without containing a high-molecular compound according to the present invention;

FIG. 3 shows a photograph (a) where an electrode line is patterned using the conductive nano ink composition according to an exemplary embodiment of the present invention, and photographs (b, c) where an electrode line is patterned using a conductive nano ink composition departing from a viscosity range of the present invention;

FIG. 4 shows a schematic view where the conductive nano ink composition according to an exemplary embodiment of the present invention is patterned through an electrohydrodynamic jet-printing method, and shows a transparent electrode patterned to have a mesh structure;

FIG. 5 shows a graph of sheet resistance and transmittance in accordance with pitches of the transparent electrode using the conductive nano ink composition according to an exemplary embodiment of the present invention;

FIG. 6 shows a cross-sectional view and a perspective view of the transparent electrode where the conductive nano ink composition according to an exemplary embodiment is patterned to have a mesh structure on a substrate;

FIG. 7 shows a cross-sectional view and a perspective view of the transparent electrode further including a coating layer on a top of the transparent electrode of FIG. 5;

FIG. 8 shows a graph of transmittance in accordance with the thickness of the coating layer of the transparent electrode according to an exemplary embodiment of the present invention;

FIG. 9 shows a distribution view of temperature measured when electricity is applied to the transparent electrode according to an exemplary embodiment of the present invention;

FIG. 10 shows a photograph of a three-dimensional (3D) transparent electrode and a transparent heater to which the transparent electrode according to an exemplary embodiment of the present invention is applicable; and

FIG. 11 shows a schematic view of a method and apparatus for patterning the conductive nano ink composition according to an exemplary embodiment of the present invention on a 3D surface.

### DETAILED DESCRIPTION OF THE EMBODIMENTS

Below, exemplary embodiments of a conductive nano ink composition according to the present invention and an electrode line and a transparent electrode using the same will be described with reference to accompanying drawings. The present invention will be more readily understood through the following exemplary embodiments, in which the following exemplary embodiments are presented for illustrative purposes only rather than limiting the scope defined in the appended claims.

According to an exemplary embodiment, a conductive nano ink composition is used for an electrode line of a transparent electrode particularly includes a conductive nano structure, a high-molecular compound, a wetting dispersant and an organic solvent as spraying liquid used while fabricating the electrode line of the transparent electrode.

The conductive nano structure is so excellent in electrical, mechanical and thermal properties that it can be an elemental substance of the conductive nano ink composition. This may have a nano particle form, or a one-dimensional (1D) nano structure such as a nano wire, a nano rod, a nano pipe, a nano belt and a nano tube. Further, the nano particle form and the 1D nano structure may be combined.

Also, the conductive nano structure may include a nano structure, or a carbon nano tube, or combination thereof, the conductive nano structure contains one or more selected from a group consisting of gold (Au), silver (Ag), aluminum (Al), nickel (Ni), zinc (Zn), copper (Cu), silicon (Si) and titanium (Ti). In particular, a silver nano wire is effective since it is easy to be self-aligned to the transparent electrode. This will be described later in detail.

The high-molecular compound, which is to control the viscosity and the optical properties of the conductive nano ink composition, may have a molecular weight of 100,000 to 1,000,000. There is no limit to the kind of natural high-molecular compound and the kind of synthetic high-molecular compound. If the high-molecular compound has a molecular weight less than 100,000, a line width becomes larger while forming the electrode pattern using the conductive nano ink composition and visibly recognized in the exterior, thereby deteriorating the reliability of the transparent electrode. On the other hand, if the high-molecular compound has a molecular weight more than 1,000,000, it is difficult to produce the ink composition since there is a limit to the dissolution of the conductive nano structure and electric conductivity is remarkably lowered.

According to an exemplary embodiment, the natural high-molecular compound may include at least one of chitosan, gelatin, collagen, elastin, hyaluronic acid, cellulose, silk fibroin, phospholipids and fibrinogen. Further, the synthetic high-molecular compound may include at least one of poly(lactic-co-glycolic acid) (PLGA), poly(lactic acid) (PLA), poly(3-hydroxybutyrate-hydroxyvalerate (PHBV), polydioxanone (PDO), polyglycolic acid (PGA), poly(lactide-caprolactone) (PLCL), poly(e-caprolactone) (PCL), poly-L-lactic acid (PLLA), poly(ether urethane urea) (PEUU), cellulose acetate, polyethylene oxide (PEO), poly(ethylene vinyl alcohol (EVOH), polyvinyl alcohol (PVA), polyethylene glycol (PEG) and polyvinylpyrrolidone (PVP). In accordance with the kinds of conductive nano structure, the natural high-molecular compound and the synthetic high-molecular compound may be combined. According to an exemplary embodiment, in the case where the silver nano wire is used as the conductive nano structure for the ink composition, PEG or PEO may be used as the high-molecular compound since it is easy to control the viscosity.

The high-molecular compound may preferably range from 0.05 to 15 parts by weight, and more preferably range from 0.1 to 10 parts by weight, per 100 parts by weight of the conductive nano structure. If the high-molecular compound is less than 0.05 parts by weight, it is impossible to perform patterning because jetting is unstable and multi-jets are discharged while the electrode line is formed using the electrohydrodynamic jet-printing, and it is impossible to form a continuous electrode pattern since the electrode line is broken. On the other hand, if the high-molecular compound is more than 15 parts by weight, the electrical properties are significantly deteriorated.

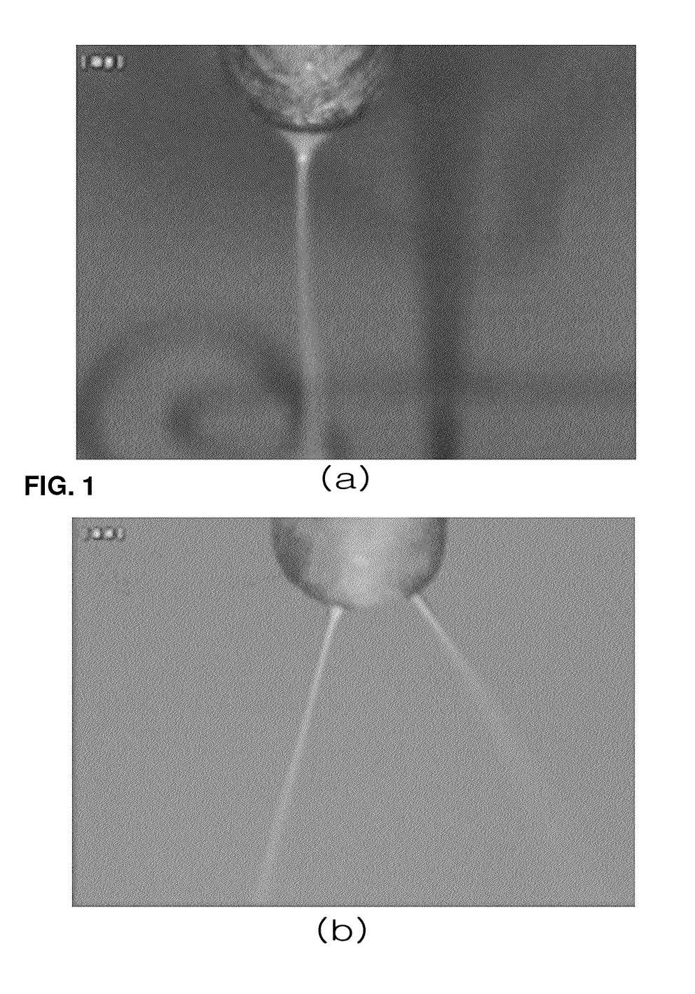

(a) of FIG. 1 shows a case of using the conductive nano ink composition according to an exemplary embodiment of the present invention, in which the jetting is stable and it is easy to perform the patterning. On the other hand, (b) of FIG. 1 shows a case of using the conductive nano ink composition containing 16 parts by weight of the high-molecular compound per 100 parts by weight of the conductive nano structure, it is impossible to perform the patterning because jetting is unstable and multi-jets occur in many directions during the discharge. Accordingly, the kind and content of high-molecular compound for maintaining uniform viscosity are important while producing the conductive nano ink composition.

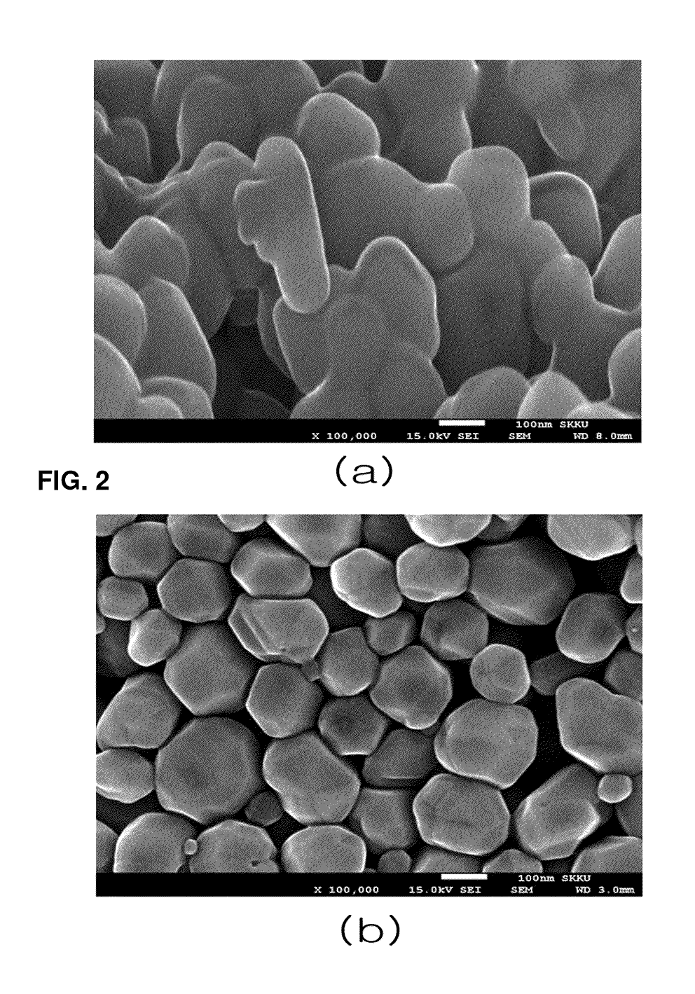

While the conductive nano structure containing no high-molecular compound has a shape that the particles of the conductive nano structure are connected (refer to (b) of FIG. 2), the conductive nano structure containing the high-molecular compound within the foregoing contents is shaped as if the conductive nano structure is coated with a film since the high-molecular compound combines with the conductive nano structure (refer to (a) of FIG. 2).

The high-molecular compound makes it possible to control the viscosity of the ink composition, thereby improving optical properties as well as jetting efficiency, and preventing the conductive nano structure from being oxidized. Thus, it is possible to achieve the transparent electrode excellent in physical properties.

The wetting dispersant is to uniformly disperse the conductive nano structure and the high-molecular compound to the organic solvent, so that the conductive nano structure and the high-molecular compound can be improved in wetting force and prevented from re-aggregation, thereby dispersion be stable.

The wetting dispersant is adsorbed onto the surface of the conductive nano structure or high-molecular compound. If the surface areas of conductive nano structure and the high-molecular compound are taken into account, the wetting dispersant may preferably range from 1 to 6 parts by weight, and more preferably range from 2 to 5 parts by weight, per 100 parts by weight of the conductive nano structure. If wetting dispersant is less than 1 parts by weight, the conductive nano structure or the high-molecular compound cannot be dispersed in the solvent, and the surface area of the high-molecular compound cannot be surrounded with the wetting dispersant, thereby making it difficult to maintain the high viscosity. On the other hand, if wetting dispersant is more than 6 parts by weight, it is uneconomical and the transparency of the conductive nano ink composition is deteriorated.

There is no limit to the kind of wetting dispersant. Preferably, a polyacrylate-based dispersant, CPT-polyacrylate-based dispersant, a polyurethane-based dispersant, a phosphate ester-based dispersant, a polyalkoxylate-based dispersant, a fatty acid-based dispersant, a silicon-based dispersant, and a mineral oil-based dispersant are effective.

The organic solvent serves to disperse the conductive nano structure. In this exemplary embodiment, the organic solvent may include an alcohol solvent, an ester solvent, or an ether solvent, which may be combined in accordance with the kinds of conductive nano structure and the kinds of high-molecular compound.

In terms of selecting the solvent for the conductive nano ink composition, a dielectric constant and a surface tension are important. Depending on the dielectric constant and the surface tension, a Taylor cone formed in the discharging unit during the electrohydrodynamic jet-printing is varied in angle and shape, thereby having an effect on the shape of the electrode line.

The dielectric constant of the organic solvent (a dielectric constant (εᵣ) at a room temperature and a frequency of 1 kHz) may preferably range from 0.5 to 60, and more preferably range from 2 to 50. If the dielectric constant is beyond the foregoing range, an irregular amount is discharged with regard to voltage applied during the electrohydrodynamic jet-printing, liquid vibrating on a nozzle is observed, and it is difficult to form the electrode line due to the multi-jets. Also, the surface tension may preferably range from 10 to 100 mN/m, and more preferably range from 20 to 70 mN/m. If the surface tension is lower than 10 mN/m, the jet is not formed even though voltage is applied during the electrohydrodynamic jet-printing. On the other hand, if the surface tension is higher than 100 mN/m, a periodic phenomenon where the jet is formed by the applied voltage and then return to a droplet state due to the surface tension is repeated.

As a preferred exemplary embodiment of the organic solvent, ethanol, butylglycol, propyleneglycol, ethoxypropanol, isobutanol, methoxy propoxypropanol, methoxypropylacetate, dipropyleneglycolmonomethylether, and tripropyleneglycolethylether are effective.

The organic solvent may preferably range from 10 to 100 parts by weight, and more preferably range from 30 to 80 parts by weight per 100 parts by weight of the conductive nano structure. If the organic solvent is less than 10 parts by weight, effective jetting is not performed. On the other hand, if the organic solvent is more than 100 parts by weight, the electrical properties are remarkably deteriorated due to less contents of the conductive nano structure.

The conductive nano ink composition having the foregoing composition and contents may preferably have a viscosity of 1,000 to 100,000cP, and more preferably have a viscosity of 1,000 to 10,000cP. The conductive nano ink composition having the viscosity within the foregoing range is transferred along a straight jet route where it is discharged in a straight direction perpendicular to a nozzle within a predetermined range from the discharging unit for discharging the ink composition when electrically radiated through the electrohydrodynamic jet-printing method. At this time, an insulating plate is placed within a section corresponding to the straight jet, so that the patterning can be performed as desired by a user.

Thus, if the conductive nano ink composition has a viscosity lower than 1,000 cP, the low viscosity causes the ink composition to be discharged in the form of not the straight jet but the droplet and it is therefore difficult to perform the patterning. That is, it is difficult to achieve the electrode line having a line width equal to or less than 20 μm, and the line width is not uniform and easily affected by humidity, temperature and the like environmental facts when being printed. On the other hand, if the conductive nano ink composition has a viscosity higher than 100,000 cP, it is difficult to pattern the electrode line having a line width equal to or less than 10 μm, thereby remarkably deteriorating the physical properties of the transparent electrode. That is, if the viscosity is low since the high-molecular compound is not contained or the content of the high-molecular compound is beyond the range according to the present invention, the continuity and straightness of the electrode pattern are affected by the low viscosity, thereby making it difficult to form the electrode pattern. Further, a plurality of dots sprayed around the electrode line causes the physical properties of the transparent electrode to be remarkably deteriorated. Therefore, it is important to control the kind and content of high-molecular compound to have a viscosity of 1,000 to 100,000 cP as described above.

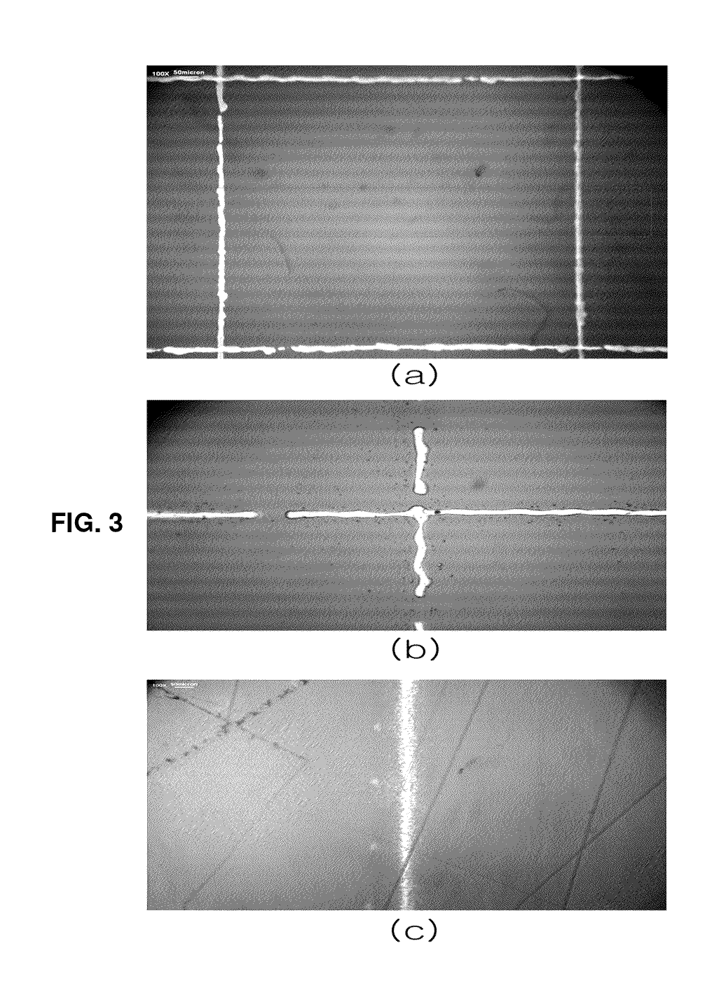

FIG. 3 shows that the electrode pattern is formed in accordance with the viscosity of the conductive nano ink composition. To form the electrode pattern through the electrohydrodynamic jet-printing, (a) shows a case of using the conductive nano ink composition having a viscosity of 5,350 cP according to an exemplary embodiment of the present invention; (b) shows a case of using the conductive nano ink composition that contains 0.08 parts by weight of the high-molecular compound per 100 parts by weight of the conductive nano structure and thus has a viscosity of 270 cP; and (c) shows a case of using the conductive nano ink composition that contains no high-molecular compound and has a viscosity of 53 cP. While the electrode line of (a) is clearly formed without discontinuity, the electrode line of (b) is often broken and does not form a continuous line and the electrode line of (c) is formed with scattered dots therearound.

Also, the conductive nano ink composition according to an exemplary embodiment of the present invention may electrically have a leaky dielectric characteristic, which is effective when an electric conductivity is between 10⁻¹⁰ s/m and 10⁻¹ s/m, and more effective when an electric conductivity is between 10⁻¹⁰ s/m and 10⁻³ s/m. That is, the conductive nano ink composition can improve physical properties as the electrode line when its conductivity is between those of benzene having very low conductivity and mercury having high conductivity. The electric conductivity of the conductive nano ink composition can be controlled in accordance with the conductive nano structures, the kinds and contents of solvent.

The foregoing ranges of the viscosity and the electric conductivity may be achieved only when the conductive nano structure, the high-molecular compound, the wetting dispersant and the organic solvent are organically mixed within the setting content ranges.

Also, the present invention relates to an electrode line formed by the foregoing conductive nano ink composition.

As described above, the conductive nano ink composition forming the electrode line may include 0.05 to 15 parts by weight of at least one high-molecular compound between the natural high-molecular compound and the synthetic high-molecular compound having a molecular weight of 100,000 to 1,000,000; 1 to 6 parts by weight of the wetting dispersant; and 10 to 100 parts by weight of the organic solvent per 100 parts by weight of the conductive nano structure. The conductive nano structure may have a nano particle, or a one-dimensional (1D) nano structure such as a nano wire, a nano rod, a nano pipe, a nano belt and a nano tube. Further, the nano particle form and the 1D nano structure may be combined. Also, the conductive nano structure may include a nano structure, or a carbon nano tube, or combination thereof, the conductive nano structure contains one or more selected from a group consisting of gold (Au), silver (Ag), aluminum (Al), nickel (Ni), zinc (Zn), copper (Cu), silicon (Si) and titanium (Ti).

The high-molecular compound includes at least one between the natural high-molecular compound and the synthetic high-molecular compound. According to an exemplary embodiment, the natural high-molecular compound may include at least one of chitosan, gelatin, collagen, elastin, hyaluronic acid, cellulose, silk fibroin, phospholipids and fibrinogen. Further, the synthetic high-molecular compound may include at least one of poly(lactic-co-glycolic acid) (PLGA), poly(lactic acid) (PLA), poly(3-hydroxybutyrate-hydroxyvalerate (PHBV), polydioxanone (PDO), polyglycolic acid (PGA), poly(lactide-caprolactone) (PLCL), poly(e-caprolactone) (PCL), poly-L-lactic acid (PLLA), poly(ether urethane urea) (PEUU), cellulose acetate, polyethylene oxide (PEO), poly(ethylene vinyl alcohol (EVOH), polyvinyl alcohol (PVA), polyethylene glycol (PEG) and polyvinylpyrrolidone (PVP).

In the case that the conductive nano ink composition is used to form the electrode line, the viscosity is constantly maintained so that the electrode line can have a line width of 0.01 to 10 μm, preferably about 5 μm, and more preferably about 1 μm. If the line width is wider than 10 μm, it is visibly recognized in the exterior, thereby deteriorating the physical properties of the transparent electrode.

The nano wire, the nano tube and the like conductive nano structure are difficult to be patterned since they are chaotically arranged without any directing point when there is no stimulus factors of surrounding environments. Regarding to this, an electric field is applied when the conductive nano ink composition achieved according to an exemplary embodiment of the present invention is patterned as the electrode line through the electrohydrodynamic jet-printing, thereby applying the electric field between the nozzle and the substrate. Thus, the conductive nano structure may be oriented and aligned by potential difference in a direction parallel with the printing direction. Therefore, the nano materials are finally oriented on the substrate in the same direction as the printing direction, and thus patterned to have a line width less than 10 μm. Also, as the conductive nano ink composition having the high viscosity is used, it is possible to achieve a height-to-width ratio (height/line width) within a range from 0.1 to 1.0, and preferably 0.2 to 0.5. With the height-to-width ratio equal to or higher than 0.1, the sheet resistance is lowered, thereby providing an excellent transparent electrode.

Also, the present invention relates to a transparent electrode using the conductive nano ink composition, in which the transparent electrode includes a substrate and an electrode pattern where an electrode line made of the conductive nano ink composition is patterned.

As described above, in accordance with the characteristics achieved by the conductive nano ink composition of the present invention, the conductive nano structure included in the electrode line patterned on the substrate, in particular, the conductive nano structure having a 1D nano structure is self-aligned in the same orientation as the printing direction.

The substrate is coated with a carbon nano tube, graphene or a conductive polymer, i.e., poly(3,4-ethylenedioxythiophene) (PEDOT), thereby providing a transparent electrode improved in the optical properties and the electric conductivity.

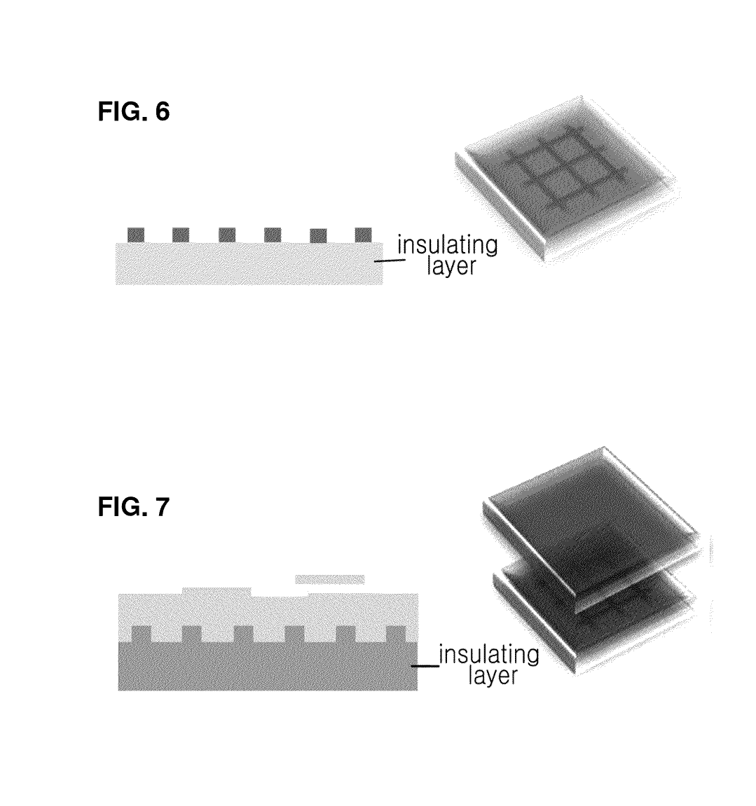

As shown in FIG. 6, a plurality of electrode lines are patterned on the substrate coated with the conductive material such as the carbon nano tube, graphene, or PEDOT. According to an exemplary embodiment of the present invention, the plurality of electrode lines are patterned to have a parallel structure or a mesh structure.

In the mesh structure, each mesh may be shaped like a diamond, a honeycomb and the like as well as a rectangle of a general grid without any limitation in accordance with use of the transparent electrode. While being patterned to have the parallel structure or the mesh structure, the pitch and the line width are important to determine the electric conductivity of the transparent electrode.

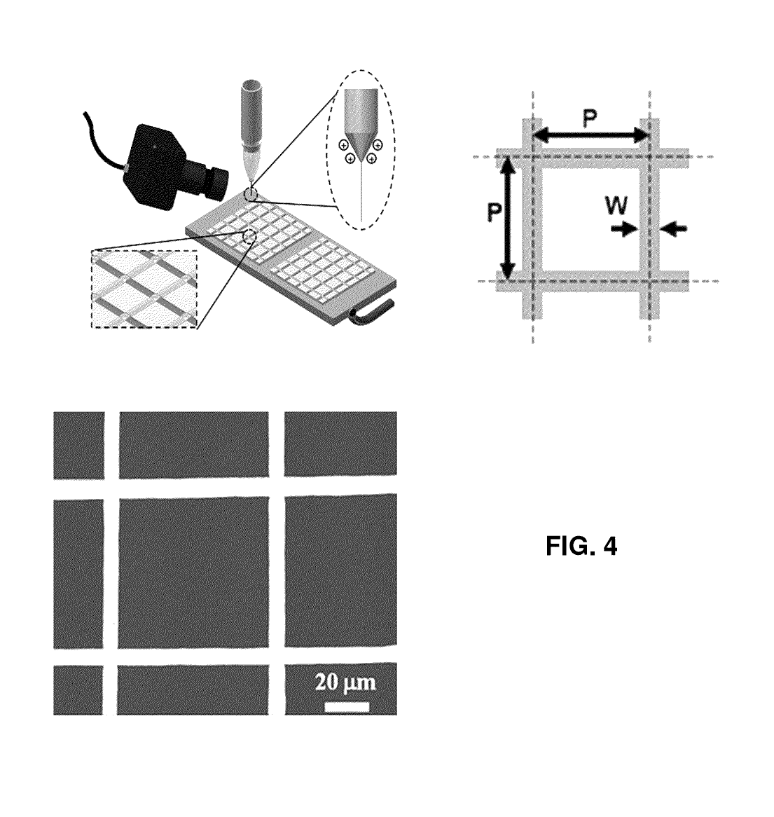

As shown in FIG. 4, the conductive nano ink composition forms a pattern.

In the electrode having a grid pattern as shown in a lower portion of FIG. 4, ‘p’ refers to a pitch between the grid electrodes, and ‘w’ refers to a line width of the grid electrode. Based on the pitch ‘p’ and the line width ‘p’, it can be represented by a fill factor (FF) how well the grid electrode can block a traveling direction of light or electromagnetic waves on a two-dimensional (2D) plane. FF can be calculated by [Expression 1] as follows.

$$F F = \frac{( pSw ) + [ ( p - w ) Sw ]}{{p}^{2}} \qquad [ Expression 1 ]$$

The sheet resistance (R_{s, Ag grid}) and the transmittance (T_{Ag grid}) are defined with FF in the following [Expression 2] and [Expression 3]. These are equations of the sheet resistance and the transmittance when silver (Ag) is used to form the grid electrode. Here, ρ_{Ag grid} is the resistance of silver, t_{Ag grid} is a thickness of the grid electrode, ξ is a constant for calculating the sheet resistance, and T_{B} is the substrate's original transmittance.

$$\begin{matrix}{R}_{s , Aggrid} = ξ \frac{{ρ}_{Aggrid}}{{t}_{Aggrid}} \frac{1}{F F} & [ Expression 2 ] \\ {T}_{Aggrid} = {T}_{B} s ( 1 \text{-} F F ) & [ Expression 3 ]\end{matrix}$$

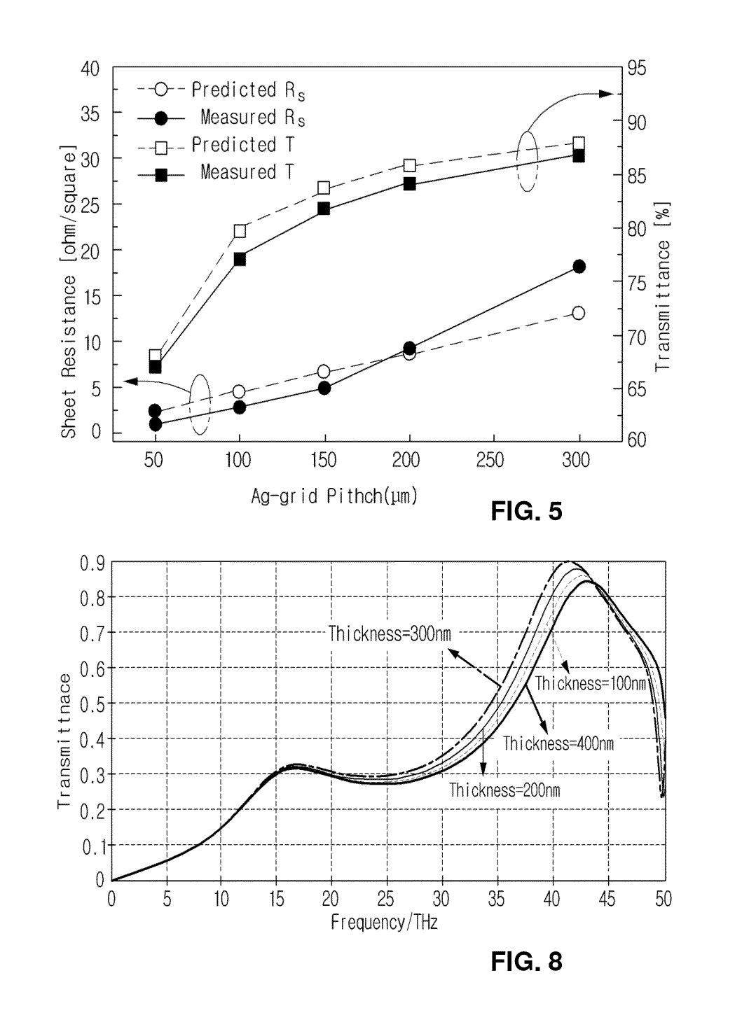

Referring to Expressions 2 and 3, the smaller the value of FF is, the better the performance of the transparent electrode is with higher transmittance and lower sheet resistance. As shown in FIG. 5, the smaller the pitch, the lower the transparency. However, the sheet resistance is also lowered at this time, thereby improving the electrical properties.

If the electrode line is a transparent electrode for a single line, it can be applied to bezel electrode-wiring for a single-side touch sensor or a television. While the conventional ITO transparent electrode substrate is patterned through lithography and etching processes, the plurality of electrode lines according to the present invention are arranged in parallel so that the transparent electrode can be directly patterned without the lithography and etching processes.

According to an exemplary embodiment of the present invention, as shown in FIG. 7, a coating layer is added on the substrate on which the electrode lines are patterned. The coating layer containing the carbon nano tube, graphene or PEDOT is formed so that adhesion between the substrate and the electrode line can be strengthened and the surface roughness is lowered, thereby providing the transparent electrode with excellent physical properties and improved electric conductivity. The coating layer may have a thickness of 10 to 300 nm, and preferably 50 to 200 nm. Referring to FIG. 8, the transmittance becomes higher while the thickness of the coating layer increases from 100 nm to 300 nm, but is lowered when the thickness of the coating layer is 400 nm. Thus, it will be appreciated that the transmittance and electric conductivity are improved by the conductive material of the coating layer up to a predetermined thickness of the coating layer rather than being unconditionally lowered as the thickness of the coating layer increases.

According to an exemplary embodiment of the present invention, the conductive material such as the carbon nano tube, a graphene or PEDOT is formed as the coating layer on the substrate, and the coating layer of the conductive material is also formed on the electrode pattern, thereby having an effect of further improving the electric conductivity of the conductive nano ink composition.

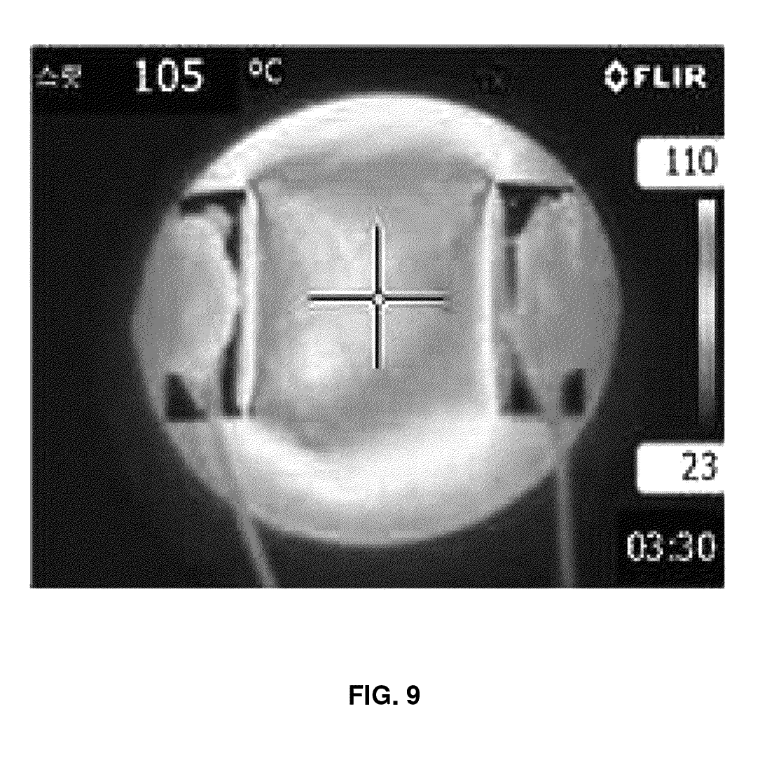

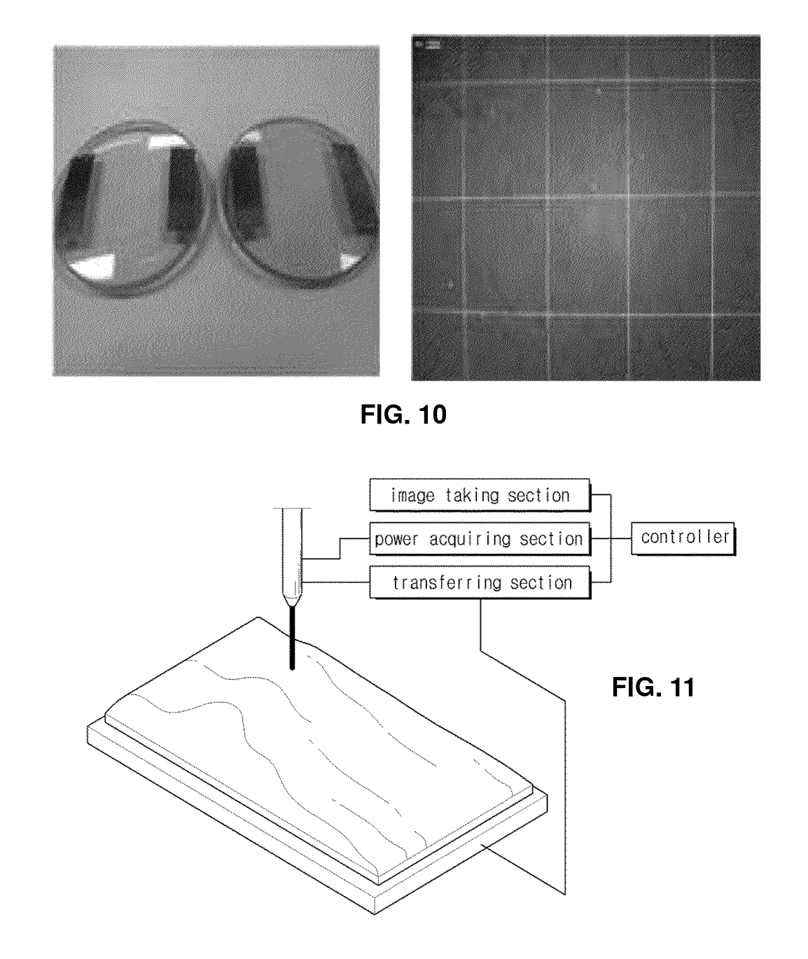

The transparent electrode according to an exemplary embodiment of the present invention may be applicable to a transparent heater. FIG. 9 shows temperature measured when electricity is applied to the transparent electrode. The transparent electrode may be applied to a transparent substrate such as glass for a building or house, glass for a vehicle, etc. and serve to demist a window, to free condensation, to melt snow, etc. Further, the transparent electrode may serve to shield electromagnetic waves and be thus applicable as a transparent electromagnetic-wave shieding material to various fields such as a display or the like. Also, the conductive nano ink composition according to an exemplary embodiment of the present invention may be applied in fabricating the transparent electrode on a three-dimensional (3D) surface as shown in FIG. 11 through the electrohydrodynamic jet-printing, so that it can be employed as a 3D transparent electrode, a transparent heater, and an electromagnetic-wave shielding material.

As described above, there is provided a conductive nano ink composition, in which a conductive nano structure, a high-molecular compound having a molecular weight of 100,000 to 1,000,000, a wetting dispersant and an organic solvent are mixed in optimal contents, so that a transparent electrode can be patterned by a simple method without repetitively performing the deposition and etching processes.

Further, there is provided an electrode line having a narrow line width of 10 μm or less as the conductive nano ink composition is discharged through the electrohydrodynamic jet-printing in accordance with the viscosity and electrical properties of the conductive nano ink composition, and thus the conductive nano structure contained in the conductive nano ink composition is self-aligned.

Also, there is provided a transparent electrode having an electrode line patterned with the conductive nano ink composition, in which upper layers of a substrate and the transparent electrode are coated with a conductive material such as a carbon nano tube, a graphene or PEDOT, thereby remarkably improving the electric conductivity.

In addition, there is provided a transparent electrode, in which the coating thickness on the transparent electrode is adjusted at a nanoscale level, so that adhesion between the substrate and the electrode line can be strengthened to improve physical properties and the light transmittance can be improved to promote optical properties, thereby maintaining the electric conductivity.

Furthermore, the conductive nano ink composition facilitates the process of patterning the transparent electrode, and is thus applicable to not only the transparent electrode but also a 2D or 3D transparent heater and an electromagnetic-wave shielding material.

Although a few exemplary embodiments of the present invention have been shown and described, it will be appreciated by those skilled in the art that changes may be made in these embodiments without departing from the principles and spirit of the invention, the scope of which is defined in the appended claims and their equivalents.

What is claimed is:

1. A conductive nano ink composition comprising:
0.05 to 15 parts by weight of a high molecular compound having a molecular weight of 100,000 to 1,000,000 and comprising at least one between a natural high-molecular compound and a synthetic high-molecular compound;
1 to 6 parts by weight of a wetting dispersant; and
10 to 100 parts by weight of an organic solvent,
per 100 parts by weight of a conductive nano structure.

2. The conductive nano ink composition according to claim 1, wherein the conductive nano structure comprises at least one of a nano particle, a nano wire, a nano rod, a nano pipe, a nano belt and a nano tube.

3. The conductive nano ink composition according to claim 1, wherein the conductive nano structure comprises a nano structure or a carbon nano tube or combination thereof, the nano structure contains one or more selected from a group consisting of gold (Au), silver (Ag), aluminum (Al), nickel (Ni), zinc (Zn), copper (Cu), silicon (Si) and titanium (Ti).

4. The conductive nano ink composition according to claim 1, wherein the natural high-molecular compound comprises at least one among chitosan, gelatin, collagen, elastin, hyaluronic acid, cellulose, silk fibroin, phospholipids and fibrinogen.

5. The conductive nano ink composition according to claim 1, wherein the synthetic high-molecular compound comprises at least one among poly(lactic-co-glycolic acid) (PLGA), poly(lactic acid) (PLA), poly(3-hydroxybutyrate-hydroxyvalerate (PHBV), polydioxanone (PDO), polyglycolic acid (PGA), poly(lactide-caprolactone) (PLCL), poly(e-caprolactone) (PCL), poly-L-lactic acid (PLLA), poly(ether urethane urea) (PEUU), cellulose acetate, polyethylene oxide (PEO), poly(ethylene vinyl alcohol (EVOH), polyvinyl alcohol (PVA), polyethylene glycol (PEG) and polyvinylpyrrolidone (PVP).

6. The conductive nano ink composition according to claim 1, wherein the organic solvent comprises at least one among an alcohol solvent, an ester solvent, and an ether solvent.

7. The conductive nano ink composition according to claim 1, wherein the conductive nano ink composition has a viscosity of 1,000 to 100,000 cP.

8. The conductive nano ink composition according to claim 1, wherein the conductive nano ink composition has an electric conductivity of 10⁻¹⁰ to 10⁻¹ S/m.

9. An electrode line of a conductive nano ink composition,
the conductive nano ink composition comprising:
0.05 to 15 parts by weight of a high molecular compound having a molecular weight of 100,000 to 1,000,000 and comprising at least one between a natural high-molecular compound and a synthetic high-molecular compound;
1 to 6 parts by weight of a wetting dispersant; and
10 to 100 parts by weight of an organic solvent,
per 100 parts by weight of a conductive nano structure.

10. The electrode line according to claim 9, wherein the conductive nano structure comprises at least one of a nano particle, a nano wire, a nano rod, a nano pipe, a nano belt and a nano tube.

11. The electrode line according to claim 9, wherein the conductive nano structure comprises a nano structure or a carbon nano tube or combination thereof, the conductive nano structure contains one or more selected from a group consisting of gold (Au), silver (Ag), aluminum (Al), nickel (Ni), zinc (Zn), copper (Cu), silicon (Si) and titanium (Ti).

12. The electrode line according to claim 9, wherein the natural high-molecular compound comprises at least one among chitosan, gelatin, collagen, elastin, hyaluronic acid, cellulose, silk fibroin, phospholipids and fibrinogen.

13. The electrode line according to claim 9, wherein the synthetic high-molecular compound comprises at least one among poly(lactic-co-glycolic acid) (PLGA), poly(lactic acid) (PLA), poly(3-hydroxybutyrate-hydroxyvalerate (PHBV), polydioxanone (PDO), polyglycolic acid (PGA), poly(lactide-caprolactone) (PLCL), poly(e-caprolactone) (PCL), poly-L-lactic acid (PLLA), poly(ether urethane urea) (PEUU), cellulose acetate, polyethylene oxide (PEO), poly(ethylene vinyl alcohol (EVOH), polyvinyl alcohol (PVA), polyethylene glycol (PEG) and polyvinylpyrrolidone (PVP).

14. The electrode line according to claim 9, wherein the electrode line has a line width of 0.01 to 1 μm.

15. A transparent electrode comprising:
a substrate; and
an electrode pattern where the electrode line according to claim 9 is patterned on the substrate.

16. The transparent electrode according to claim 15, wherein the conductive nano structure of the electrode line patterned on the substrate is self-aligned in the same orientation as a printing direction.

17. The transparent electrode according to claim 15, wherein the substrate is coated with a carbon nano tube, a graphene or poly(3,4-ethylenedioxythiophene)(PEDOT).

18. The transparent electrode according to claim 15, wherein the electrode pattern comprises a plurality of electrode lines, and the plurality of electrode lines are patterned to have a parallel structure or a mesh structure.

19. The transparent electrode according to claim 15, further comprising a coating layer on the substrate where the electrode line is patterned, wherein the coating layer comprises a carbon nano tube, a graphene or poly(3,4-ethylenedioxythiophene)(PEDOT).

20. The transparent electrode according to claim 19, wherein the coating layer has a thickness of 10 to 300 nm.
